(19) United States
(12) Patent Application Publication
(10) Pub. No.: US 2019/0179225 A1
(43) Pub. Date: Jun. 13, 2019

(54) PHOTOMASKS, METHODS OF MANUFACTURING PHOTOMASKS, AND METHODS OF MANUFACTURING SEMICONDUCTOR DEVICE USING PHOTOMASKS

(71) Applicant: Samsung Electronics Co., Ltd., Suwon-si (KR)

(72) Inventors: Hwan Seok SEO, Suwon-si (KR); Myoung Soo LEE, Yongin-si (KR); Byung Hoon LEE, Seoul (KR)

(21) Appl. No.: 16/016,779

(22) Filed: Jun. 25, 2018

(30) Foreign Application Priority Data
Dec. 11, 2017 (KR) 10-2017-0169135

(51) Int. Cl. G03F 1/22; G03F 1/54; G03F 1/52; G03F 1/42

(52) U.S. Cl. CPC G03F 1/22; G03F 1/54; H01L 21/0274; G03F 1/42; G03F 1/52

(57) ABSTRACT

A photomask is provided. The photomask comprises: a low thermal expansion material (LTEM) substrate including a first surface and a second surface; a reflective layer disposed on the first surface of the low thermal expansion material substrate and including first material layers and second material layers, which are stacked alternately; a light absorbing pattern on the reflective layer; and a conductive layer on the second surface of the low thermal expansion material substrate, wherein the low thermal expansion material substrate includes a correction defect correcting the light absorbing pattern, and the conductive layer is one of ruthenium oxide (RuO₂), iridium oxide (IrO₂), and/or a combination thereof.

### CROSS-REFERENCE TO RELATED APPLICATIONS

This application claims priority under 35 U.S.C. § 119 to Korean Patent Application No. 10-20179-0169135 filed on Dec. 11, 2017 in the Korean Intellectual Property Office (KIPO), the disclosure of which is incorporated herein in its entirety by reference.

### BACKGROUND

The present inventive concept relates to a photomask.

Recently, with the development of information media, functions of a semiconductor device have been rapidly developed. In order to increase the competitiveness of a semiconductor device, high integration of a low-cost and high-quality semiconductor device may be beneficial. The interval between the patterns of a semiconductor device gradually decreases for high integration. Currently, a photolithography process using a widely used ArF excimer laser as a light source has a limitation in realizing a line width of 32 nm or less. In order to realize a line width of 32 nm or less, immersion photolithography, double patterning, and the like have been introduced, but still have limitations.

In order to solve such a problem, photolithography equipment using extreme ultraviolet (EUV) as a light source has been introduced. However, since extreme ultraviolet is greatly attenuated by the atmosphere and is absorbed by almost all materials, a transmissive photomask used in known ArF photolithography cannot be used. Therefore, a photomask including a reflective layer is used in an extreme ultraviolet photolithography process.

However, since a photomask uses the reflective properties of light, registration errors may occur when the photomask is slightly bent or deformed.

### SUMMARY

It is noted that aspects of the inventive concept described with respect to one embodiment, may be incorporated in a different embodiment although not specifically described relative thereto. That is, all embodiments and/or features of any embodiment can be combined in any way and/or combination. These and other objects and/or aspects of the present inventive concept are explained in detail in the specification set forth below.

An aspect of the present inventive concept is to provide a photomask in which correction defects are formed in a substrate.

Another aspect of the present inventive concept is to provide a photomask including a conductive layer having a transmittance of 10% or more and a surface resistance of 200 ohm/sq or less in a visible light range.

Still another aspect of the present inventive concept is to provide a method of manufacturing a photomask including a conductive layer having a transmittance of 10% or more and a surface resistance of 200 ohm/sq or less in a visible light range.

Still another aspect of the present inventive concept is to provide a method manufacturing a semiconductor device using a photomask including a conductive layer having a transmittance of 10% or more and a surface resistance of 200 ohm/sq or less in a visible light range.

According to some embodiments of the present inventive concept, a photomask includes a low thermal expansion material (LTEM) substrate including a first surface and a second surface, a reflective layer on the first surface of the low thermal expansion material substrate, the reflective layer including first material layers and second material layers, which are stacked alternately, a light absorbing pattern on the reflective layer, and a conductive layer on the second surface of the low thermal expansion material substrate. The low thermal expansion material substrate includes a correction defect correcting the light absorbing pattern, and the conductive layer is formed from one of ruthenium oxide (RuO₂), iridium oxide (IrO₂), and/or a combination thereof.

According to some embodiments of the present inventive concept, a method of manufacturing a photomask includes forming a low thermal expansion material (LTEM) substrate including a first surface opposing a second surface, forming a reflective layer on the first surface of the low thermal expansion material substrate, the reflective layer including first material layers and second material layers, which are stacked alternately, forming a light absorbing layer on the reflective layer, and forming a conductive layer on the second surface of the low thermal expansion material substrate, wherein the conductive layer is from one of ruthenium oxide (RuO₂), iridium oxide (IrO₂), and/or a combination thereof.

According to some embodiments of the present inventive concept, a method of manufacturing a photomask includes forming a mask structure including a conductive layer, a low thermal expansion material (LTEM) substrate, a reflective layer, and/or a light absorbing layer, which are sequentially stacked, the conductive layer being formed from one of ruthenium oxide (RuO₂), iridium oxide (IrO₂), and/or a combination thereof, patterning the light absorbing layer to form a light absorbing pattern, and forming a correction defect correcting the light absorbing pattern in the low thermal expansion material substrate.

However, aspects of the present inventive concept are not restricted to the one set forth herein. The above and other aspects of the present inventive concept will become more apparent to one of ordinary skill in the art to which the present inventive concept pertains by referencing the detailed description of the present inventive concept given below.

### BRIEF DESCRIPTION OF THE DRAWINGS

The above and other aspects and features of the present inventive concept will become more apparent by describing in detail example embodiments thereof with reference to the attached drawings, in which:

FIG. 1 is an example view illustrating a photomask according to some embodiments.

FIG. 2 is an example flow chart illustrating a method of manufacturing a photomask according to some embodiments.

FIGS. 3 and 4 are example views for explaining the processes of forming the respective layers to manufacture a photomask according to some embodiments.

FIGS. 5A to 6C are example views for explaining a patterning process according to some embodiments.

FIG. 7 is an example flowchart for explaining a method of detecting registration errors according to some embodiments.

FIG. 8 is a schematic view of extreme ultraviolet lithography equipment for illustrating a process of detecting registration errors according to some embodiments.

FIGS. 9A and 9B are example views for explaining registration errors according to some embodiments.

FIGS. 10A and 10B are example views for explaining correction positions of a photomask according to some embodiments.

FIGS. 11A and 11B are example views for explaining a process of correcting registration errors according to some embodiments.

FIG. 12 is an example flowchart for explaining a method of manufacturing a photomask according to some embodiments.

FIG. 13 is an example flowchart for explaining a method of manufacturing a semiconductor device using the photomask according to some embodiments.

### DETAILED DESCRIPTION

Some of the components illustrated herein may be exaggerated or reduced to facilitate understanding. That is, some components may be not scaled with the same ratio in some drawings.

Hereinafter, embodiments of the present inventive concept will be described with reference to the attached drawings.

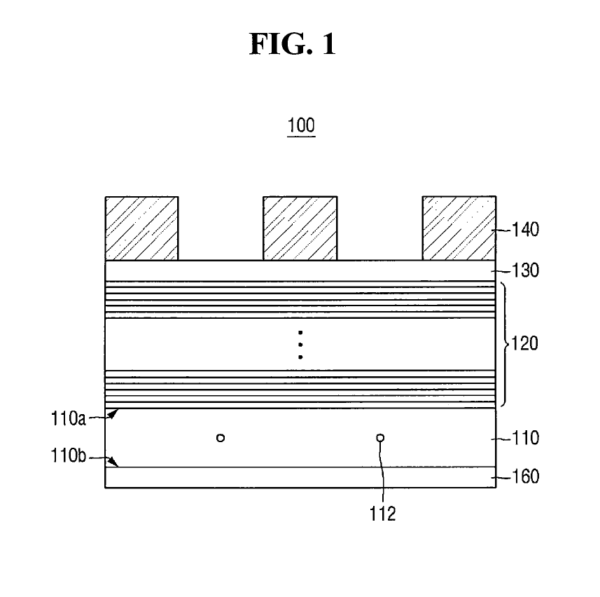

FIG. 1 is an example view illustrating a photomask according to some embodiments. For example, a photomask 100 may be an BUY photomask that may be mounted in an exposure apparatus that uses extreme ultraviolet light as a light source.

The present inventive concept relates to a photomask, a method of manufacturing a photomask, and a method of manufacturing a semiconductor device using the photomask.

Referring to FIG. 1, the photomask 100 according to some embodiments may includes a low thermal expansion material (LTEM) substrate 110, a reflective layer 120, a capping layer 130, and a light absorbing pattern 140.

The low thermal expansion material substrate 110 may include a first surface 110a and a second surface 110b, opposing each other. It will be understood that, although the terms first, second, third, etc. may be used herein to describe various elements, elements should not be limited by these terms; rather, these terms are only used to distinguish one element from another element. Thus, a first element discussed below could be termed a second element without departing from the scope of the present inventive concepts.

The low thermal expansion material substrate 110 may be formed from a material having a low thermal expansion coefficient. The low thermal expansion coefficient may quantify how the size of an object such as a substrate changes with a change in temperature. For example, the low thermal expansion material substrate 110 may have a thermal expansion coefficient of 0±1.0×10⁻⁷/° C. However, the present inventive concept is not limited thereto. The photomask 100 may be deformed by an external factor. The deformation of the photomask 100 may be warping or a distortion of the photomask 100. In this case, the pattern transferred using the deformed photomask 100 may be distorted. For example, when extreme ultraviolet light is incident on the photomask 100, heat may be generated inside the photomask 100. The deformation of the photomask 100 may be caused by the heat generated inside the photomask 100. Therefore, in order to reduce or minimize the deformation of the photomask 100 due to heat, the low thermal expansion material substrate 110 may be used in the manufacture of the photomask 100. The low thermal expansion material substrate 110 may be, for example, an LTEM glass substrate.

Further, the low thermal expansion material substrate 110 may have a high flatness. The photomask 100 according to some embodiments may utilize the reflective properties of light. Therefore, the low thermal expansion material substrate 110 may be required to have a higher flatness. When the flatness of the low thermal expansion material substrate 110 is relatively low, a pattern transferred using the photomask 100 may be distorted. The distortion of the pattern may be included in a registration error to be described later. For example, the low thermal expansion material substrate 110 may have a flatness of 60 nm or less, but the present inventive concept is not limited thereto.

Further, the low thermal expansion material substrate 110 may include correction defects 112 therein. The corrective defects 112 may be used to correct registration errors. A detailed description of the correction defects 112 will be described later.

The reflective layer 120 may be disposed on the first surface 110a of the low thermal expansion material substrate 110. The reflective layer 120 may reflect the extreme ultraviolet light irradiated to the photomask 100. The reflective layer 120 may include first material layers and second material layers. In the reflective layer 120, the first material layers and the second material layers may be alternately stacked according to some embodiments. The pair of the first material layer and the second material layer may be stacked a plurality of times. The refractive index of the first material layer may be lower than the refractive index of the second material layer. For example, the reflective layer 120 may include silicon (Si) layers and molybdenum (Mo) layers. The silicon (Si) layers and the molybdenum (Mo) layers may be alternately stacked. The pair of the silicon (Si) layer and the molybdenum (Mo) layer may be stacked 40 to 60 times in some embodiments. However, the number of times of stack of the pairs of the first material layers and the second material layers in the reflective layer 120 may change depending on the type and thickness of a material. The reflective layer 120 may be formed using, for example, a sputtering process.

The capping layer 130 may be disposed on the reflective layer 120. The capping layer 130 can prevent the reflective layer 120 from oxidizing. In addition, the capping layer 130 can prevent the reflective layer 120 from being damaged. The capping layer 130 may be formed from a metal material such as ruthenium (Ru), tantalum (Ta), vanadium (V), zirconium (Zr), or niobium (Nb), or a combination thereof. However, the present inventive concept is not limited thereto. For example, the capping layer 130 may be formed from a silicon (Si) layer and/or a silicon oxide (SiO₂) layer. However, in some embodiments, the capping layer 130 may be omitted.

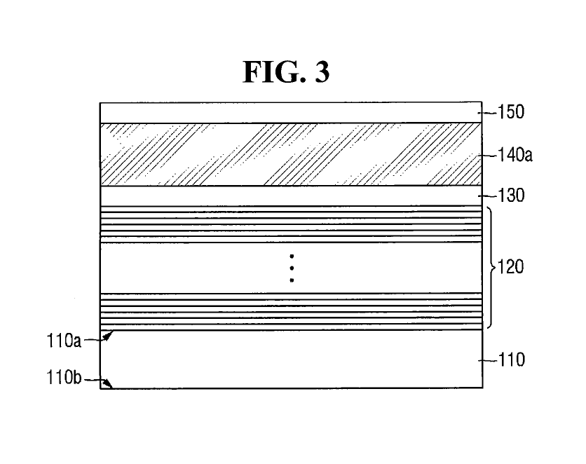

The light absorbing pattern 140 may be disposed on the capping layer 130. In some embodiments, if the capping layer 130 is omitted, the light absorbing pattern 140 may be disposed on the reflective layer 120. The light absorption pattern 140 may absorb at least a part of the irradiated extreme ultraviolet light. The light absorbing pattern 140 may be formed by patterning a light absorbing layer 140a (FIG. 3). The light absorbing pattern 140 may have a relatively low reflectance for extreme ultraviolet light. Further, the light absorbing pattern 140 may have a relatively high absorbance for extreme ultraviolet light. In other words, the reflectance of the light absorbing pattern 140 may be lower than the reflectance of the reflective layer 120 and/or the capping layer 130. Further, the absorbance of the light absorbing pattern 140 may be higher than the absorbance of the reflective layer 120 and/or the capping layer 130. The light absorbing pattern 140 may be formed from a compound of at least one of tantalum (Ta), cobalt (Co), cadmium (Cd), nickel (Ni), and palladium (Pd) and at least one of hafnium (Hf), silicon (Si), zirconium (Zr), germanium (Ge), oxygen (O), nitrogen (N), boron (B), and hydrogen (H). For example, the light absorbing pattern 140 may be formed from TaBN. As used herein, the term “and/or” includes any and all combinations of one or more of the associated listed items. Expressions such as “at least one of,” when preceding a list of elements, modify the entire list of elements and do not modify the individual elements of the list.

In other words, when extreme ultraviolet light is irradiated onto the photomask 100, the extreme ultraviolet light irradiated onto the reflective layer 120 may be reflected by the reflective layer 120. Further, the extreme ultraviolet light irradiated onto the light absorbing pattern 140 may be absorbed by the light absorbing pattern 140.

A conductive layer 160 may be disposed on the second surface 110b of the low thermal expansion material substrate 110. The conductive layer 160 may be attached to an electrostatic chuck. In order for the conductive layer 160 to be stably attached to the electrostatic chuck, the conductive layer 160 may have a surface resistance of 200 ohm/sq or less. When the conductive layer 160 is attached to the electrostatic chuck, the electrostatic chuck can use an electrostatic force. In other words, the photomask 100 may be attached to extreme ultraviolet photolithography equipment by the electrostatic force.

By the electrostatic force, an attractive force may be generated between the conductive layer 160 and the electrostatic chuck. Therefore, even if deformation (for example, warpage, bending and/or bowing) of the photomask 100 occurs, the deformation of the photomask 100 may be partially restored by the attractive force between the conductive layer 160 and the electrostatic chuck. In addition, the photomask 100 may be stably attached to the electrostatic chuck by the attractive force between the conductive layer 160 and the electrostatic chuck. As described above, when the photomask 100 is deformed, the photomask 100 may undergo registration errors. The registration errors of the photomask 100 may be reduced because the conductive layer 160 is attached to the electrostatic chuck by the electrostatic force to partially restore the deformation of the photomask 100.

The transmittance of the conductive layer 160 in the visible light range may be 10% or more. The visible light range may be a wavelength band of a laser used as correction mechanism for registration errors. The wavelength of the laser may be 532 nm. As will be described later, in order to correct the registration errors, the laser in the visible light range may also be applied toward the conductive layer 160 from outside. At this time, at least a part of the laser irradiated onto the conductive layer 160 may penetrate the conductive layer 160. Here, correction defects may be generated in the low thermal expansion material substrate 110 by the laser having penetrated the conductive layer 160. The corrective defects may be used to correct registration errors. In order to generate correction defects, it may be required that a predetermined level or more of the laser reaches the low thermal expansion material substrate 110. Therefore, the transmittance of the conductive layer 160 may be required to be 10% or more in the visible light range to allow penetration by the laser. Details of the process of correcting the registration errors will be described later.

The photomask 100 may be repeatedly loaded/unloaded to/from the electrostatic chuck of the extreme ultraviolet photolithography equipment. At this time, physical stress may be applied to the conductive layer 160. Further, the photomask 100 may require periodic chemical and/or physical cleaning. During cleaning, chemical/physical stress may be applied to the conductive layer 160. Therefore, the conductive layer 160 may be formed from a material having sufficient physical/chemical durability for viability during operations such as cleaning.

In order to satisfy all of the above-described conditions, for example, the conductive layer 160 may be formed from ruthenium oxide (RuO₂), iridium oxide (IrO₂), or a combination thereof. In other words, the conductive layer 160 formed from ruthenium oxide (RuO₂), iridium oxide (IrO₂), or a combination thereof may have a transmittance of 10% or more in the visible light range. Further, the conductive layer 160 formed from ruthenium oxide (RuO₂), iridium oxide (IrO₂), or a combination thereof may have a surface resistance of 200 ohm/sq or less. Moreover, the conductive layer 160 formed from ruthenium oxide (RuO₂), iridium oxide (IrO₂), or a combination thereof may have sufficient chemical/physical durability.

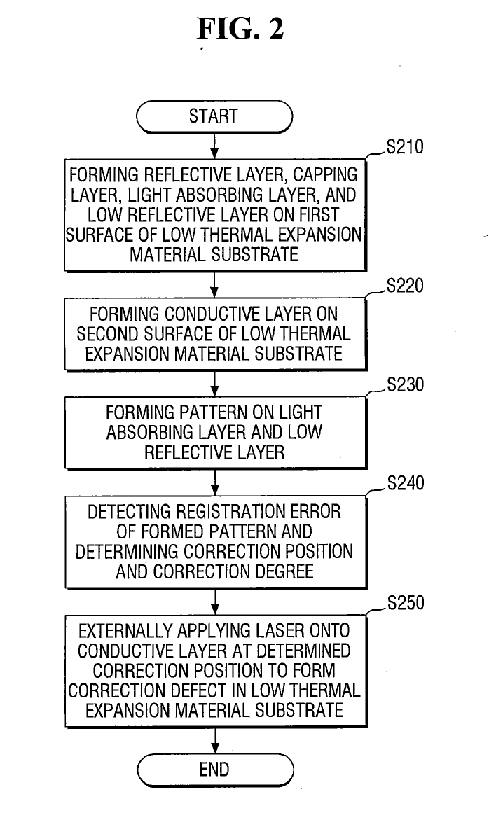

FIG. 2 is an example flow chart illustrating a method of manufacturing a photomask according to some embodiments.

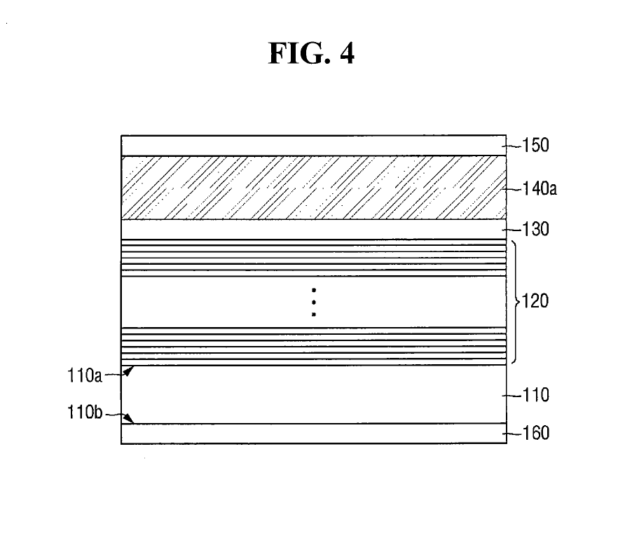

FIGS. 3 and 4 are example views for explaining the processes of forming the respective layers to manufacture a photomask according to some embodiments.

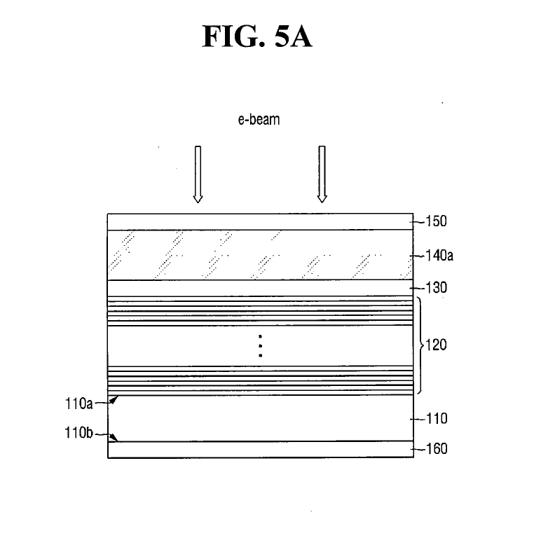

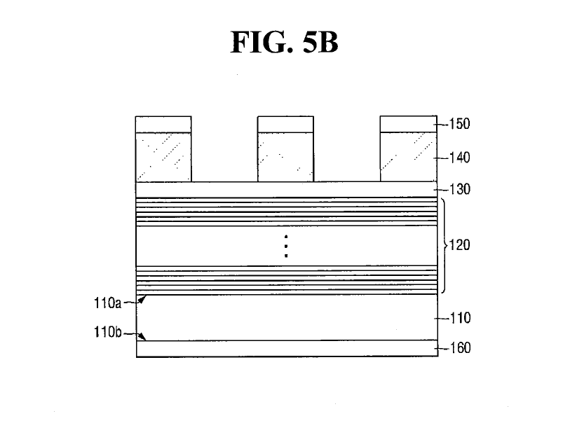

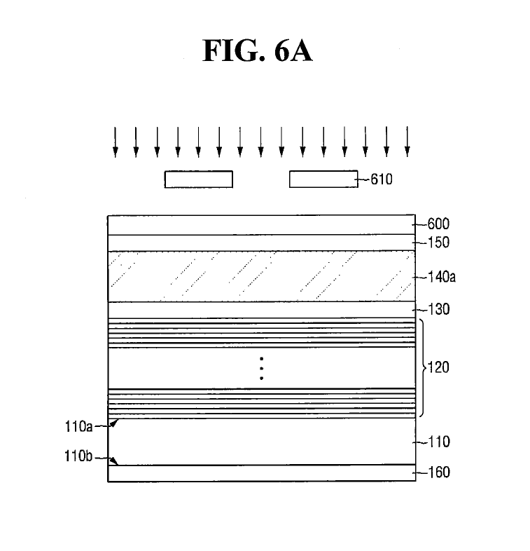

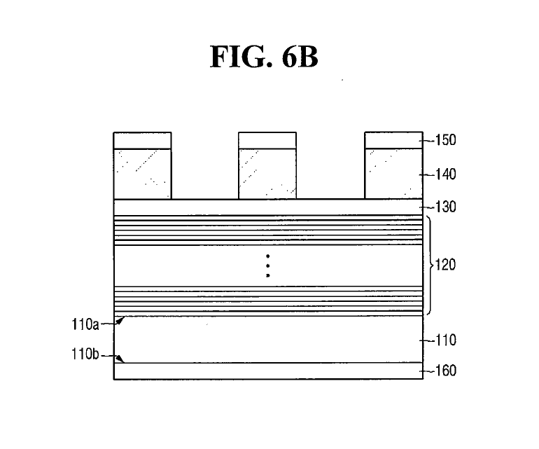

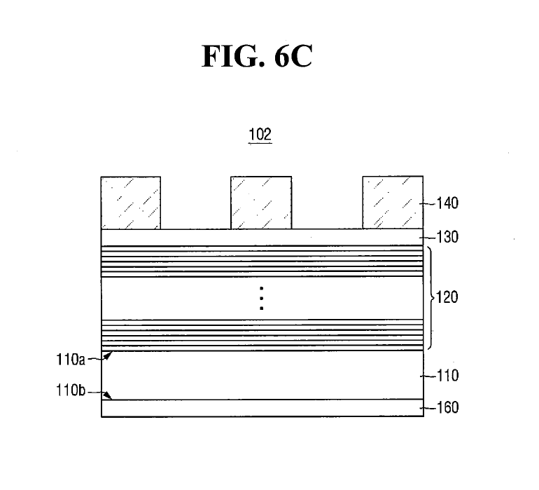

FIGS. 5A to 6C are example views for explaining a patterning process according to some embodiments.

Referring to FIGS. 2 and 3, a reflective layer 120, a capping layer 130, a light absorbing layer 140a, and a low reflective layer 150 may be sequentially formed on the first surface 110a of a low thermal expansion material substrate 110 (S210).

First, the reflective layer 120 may be formed on the first surface 110a of the low thermal expansion material substrate 110.

The reflective layer 120, as described above, may be formed by alternately stacking the first material layers and the second material layers. The reflective layer 120 may be formed, for example, by stacking 40 pairs of silicon (Si) layers and molybdenum (Mo) layers. According to some embodiments, the silicon (Si) layer may be formed by a sputtering process that targets silicon (Si). Thereafter, the molybdenum (Mo) layer may be formed by a sputtering process that targets molybdenum (Mo). By repeating such a sputtering process, the reflective layer 120 in which silicon (Si) layers and molybdenum (Mo) layers are alternately stacked may be formed on the first surface 110a of the low thermal expansion substrate 110. Each of the silicon (Si) layer and the molybdenum (Mo) layer may be, for example, 2 nm to 5 nm. However, the present inventive concept is not limited to such materials, thicknesses, number of layers and/or formation methods.

The capping layer 130 may be formed on the reflective layer 120. The capping layer 130 may be formed from, for example, ruthenium (Ru). The thickness of the capping layer 130 may be, for example, 0.5 nm to 10 nm. However, the present inventive concept is not limited to such materials and thicknesses. In some embodiments, the formation of the capping layer 130 may be omitted. Further, in some embodiments, at least a part of the capping layer 130 may be etched while a light absorbing pattern 140 is formed.

The light absorbing layer 140a may be formed on the capping layer 130. The light absorbing layer 140a may be formed from a compound of at least one of tantalum (Ta), cobalt (Co), cadmium (Cd), nickel (Ni), and palladium (Pd) and at least one of hafnium (Hf), silicon (Si), zirconium (Zr), germanium (Ge), oxygen (O), nitrogen (N), boron (B), and hydrogen (H). For example, the light absorbing layer 140a may be formed from TaBN. The thickness of the light absorbing layer 140a may be, for example, 30 nm to 200 nm. However, the present inventive concept is not limited to such materials and thicknesses.

The low reflective layer 150 may be formed on the light absorbing layer 140a. The low reflective layer 150 may provide a relatively low reflectance in the wavelength band of inspection light. The inspection light may be used to check whether the light absorption pattern 140 is properly formed. For example, the wavelength band of the inspection light may be 190 nm to 250 nm. The low reflective layer 150 may reflect a small amount of light in the wavelength band of 190 nm to 250 nm. A reflectance value of the low reflective layer 150 may be relatively less than reflectance values of the absorbing layer 140a, the absorbing pattern 140, the capping layer 130, and/or the reflective layer 120 in the wavelength band of 190 nm to 250 nm. In some embodiments, the low reflective layer 150 may have a reflectance value less than 0.2, indicating that less than 20% of the light is reflected by the low reflective layer 150. The role of the low reflective layer 150 will be described later in detail. For example, the low reflective layer 150 may be formed from TaBO. For example, the thickness of the low reflective layer 150 may be between 5 nm and 25 nm. However, the present inventive concept is not limited to such materials and thicknesses. In some embodiments, the formation of the low reflective layer 150 may be omitted.

Referring to FIGS. 2 and 4, a conductive layer 160 may be formed on the second surface 110b of the low thermal expansion material substrate 110 (S220). The conductive layer 160 may be formed from ruthenium oxide (RuO₂), iridium oxide (IrO₂), and/or a combination thereof. For example, the conductive layer 160 may be formed from ruthenium oxide (RuO₂). The thickness of the conductive layer 160 formed from ruthenium oxide (RuO₂) may be 30 nm to 128 nm. The transmittance of the conductive layer 160 formed from ruthenium oxide (RuO₂) may be 20% to 55% in the visible light range. Further, the surface resistance of the conductive layer 160 formed from ruthenium oxide (RuO₂) may be 25 ohm/sq to 100 ohm/sq.

In some embodiments, reactive sputtering may be used when forming the conductive layer 160 on the second surface 110b of the low thermal expansion material substrate 110. For example, a reaction sputtering process may be performed by selecting at least one of ruthenium (Ru) and iridium (Ir) as a target in an argon (Ar) gas and oxygen (O₂) gas atmosphere. The conductive layer 160 may be formed by such a reactive sputtering process, but the present inventive concept is not limited thereto. Those skilled in the art may form the conductive layer 160 in various manners. For example, the conductive layer 160 may be formed by an atomic layer deposition (ALD) process or a physical vapor deposition (PVD) process.

Referring to FIG. 2, the light absorbing layer 140a and the low reflective layer 150 may be patterned (S230). In some embodiments, when the formation of the low reflective layer 150 is omitted, only the light absorbing layer 140a may be patterned. The patterned light absorbing layer 140a is referred to as a light absorbing pattern 140. Hereinafter, for convenience of explanation, the present inventive concept will be described based on a case where the low reflective layer is formed.

Referring to FIGS. 5A and 5B, in some embodiments, the light absorbing layer 140a and the low reflective layer 150 may be patterned by an e-beam process. In the e-beam process, electrons may collide with the light absorbing layer 140a and the low reflective layer 150. The light absorbing layer 140a and the low reflective layer 150 may be patterned by colliding with electrons. Although it is illustrated in FIGS. 5A and 5B that the light absorbing layer 140a and the low reflective layer 150 are patterned by the e-beam process, the present inventive concept is not limited thereto. For example, the light absorbing layer 140a and the low reflective layer 150 may be patterned by an ion-beam process.

Referring to FIGS. 6A and 6B, in some embodiments, the light absorbing layer 140a and the low reflective layer 150 may be patterned by a photolithography process. A photoresist 600 may be applied on the low reflective layer 150. The photoresist 600 may be exposed and developed using a photomask 610. The light absorbing layer 140a and the low reflective layer 150 may be etched and patterned in accordance with the pattern of the developed photoresist 600. After the light absorbing layer 140a and the low reflective layer 150 are patterned, the photoresist 600 may be removed.

In some embodiments, after the light absorbing layer 140a and the low reflective layer 150 are patterned, the pattern thereof may be inspected using inspection equipment (for example, a microscope). For example, the wavelength band of the inspection equipment may be between 190 nm to 250 nm. Here, as described above, the low reflective layer 150 may have a relatively low reflectance in the wavelength band of the inspection equipment. The low reflective layer 150 may provide sufficient contrast when inspecting the pattern thereof.

In other words, the reflectance of the light absorbing layer 140a and the light absorbing pattern 140 may be relatively low in the wavelength band of extreme ultraviolet light. Further, the absorbance of the light absorbing layer 140a and the light absorbing pattern 140 may be relatively high in the wavelength band of the extreme ultraviolet light. However, the light absorbing layer 140a and the light absorbing pattern 140 may have a relatively high reflectance in different wavelength bands. For example, the reflectance of the light absorbing layer 140a and the light absorbing pattern 140 may be relatively high in the wavelength band of the inspection equipment. Since the reflectance of the light absorbing layer 140a and the light absorbing pattern 140 is high in the wavelength band of the inspection equipment, the patterns thereof may be difficult to visually inspect. Accordingly, the low reflective layer 150 having a low reflectance in the wavelength band of the inspection equipment may be formed on the light absorbing layer 140a. At this time, since the reflectivity of the low reflective layer 150 is low, the low reflective layer 150 may provide sufficient contrast. Therefore, the pattern of the low reflective layer 150 may be visually inspected.

After the inspection of the pattern is completed, the low reflective layer 150 may be removed as shown in FIG. 6C.

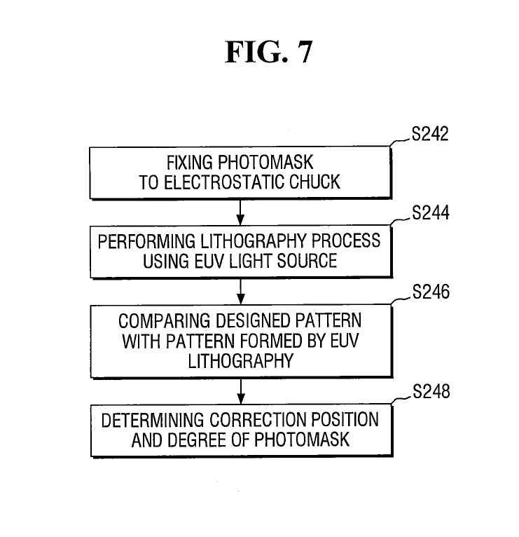

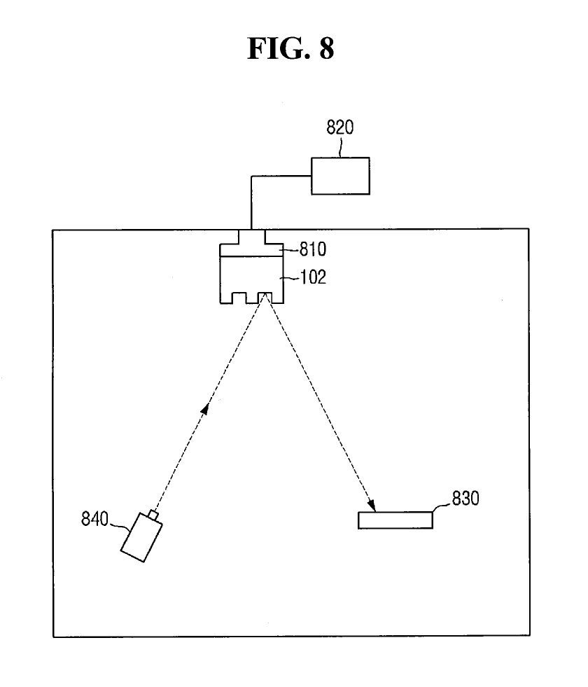

Referring to FIG. 2 again, registration errors of the pattern may be detected, and the correction position and degree thereof may be determined (S240). Hereinafter, details thereof will be described with reference to FIGS. 7 and 8.

FIG. 7 is an example flowchart for explaining a method of detecting registration errors according to some embodiments.

FIG. 8 is a schematic view of extreme ultraviolet lithography equipment for illustrating a process of detecting registration errors according to some embodiments.

For convenience of explanation, the identification number of the photomask before registration error correction is expressed by 102, and the identification number of the photomask after registration error correction is expressed by 100.

The photomask 102 is fixed to an electrostatic chuck 810 (S242). More specifically, the electrostatic chuck 810 may be connected to a power source 820 to apply a voltage to the electrostatic chuck 810. When an anode or a cathode is applied to the electrostatic chuck 810 from the power source 820, the conductive layer 160 of the photomask 102 may be charged in an opposite polarity to the electrostatic chuck 810. Thus, an electrostatic force may be generated between the electrostatic chuck 810 and the conductive layer 160. As a result, due to an electrical attractive force between the electrostatic chuck 810 and the conductive layer 160, the photomask 102 may be fixed to the electrostatic chuck 810. In this case, since the surface resistance of the conductive layer 160 is 200 ohm/sq or less, the photomask 102 may be stably fixed to the electrostatic chuck 810.

Subsequently, a lithography process is performed, and a pattern is formed on a substrate 830 using an extreme ultraviolet light source 840 (S244).

Specifically, a photoresist for extreme ultraviolet light may be applied onto the substrate 830. Then, extreme ultraviolet light may be irradiated to the photomask 102 from the extreme ultraviolet light source 840. At least a part of the extreme ultraviolet light irradiated to the reflective layer 120 of the photomask 102 may be reflected. The extreme ultraviolet light reflected from the reflective layer 120 may be incident on the substrate 830 coated with the photoresist for extreme ultraviolet light. Due to the incident extreme ultraviolet light, the photoresist for extreme ultraviolet light on the substrate 830 may be baked. The portion where the extreme ultraviolet light is not exposed or the portion where the extreme ultraviolet light is exposed may be removed by using a suitable solvent. In other words, a pattern may be primarily formed by performing an extreme ultraviolet photolithography process using the photomask 102.

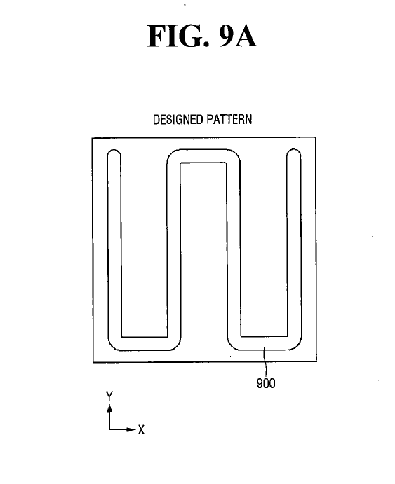

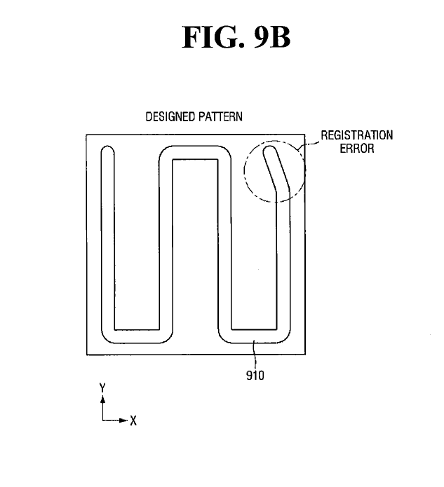

Subsequently, registration errors may be detected by comparing the initially designed pattern with the primarily formed pattern (S246). The registration errors may mean that the formed pattern is distorted. Further, the registration errors may mean that the formed pattern is not transferred to an accurate position. For example, the registration errors may be caused by the flatness of the photomask 102. Further, the registration errors may be caused when at least a part of the light absorbing pattern 140 is not accurately located at a predetermined position. Details thereof will be described with reference to FIGS. 9A and 9B.

FIGS. 9A and 9B are example views for explaining registration errors according to some embodiments.

Referring to FIGS. 9A and 9B, the pattern 910 formed through the extreme ultraviolet lithography process using the photomask 102 may be compared with the initially designed pattern 900. Comparing the formed pattern 910 with the initially designed pattern 900, it can be found that a registration error occurs at the right upper end of the formed pattern 910. Although it is shown in FIG. 9B that a registration error occurs only for a part of the formed pattern 910, the present inventive concept is not limited thereto. For example, registration errors may occur for all of the formed patterns 910. The method of detecting registration errors described herein is merely example. Those skilled in the art may use various methods to detect registration errors. For example, alignment marks may be formed on the substrate 830 and the photomask 102, respectively. The substrate 830 may be patterned using the photomask 102. The registration errors may be detected by comparing the alignment mark of the formed pattern with the alignment mark of the substrate 830.

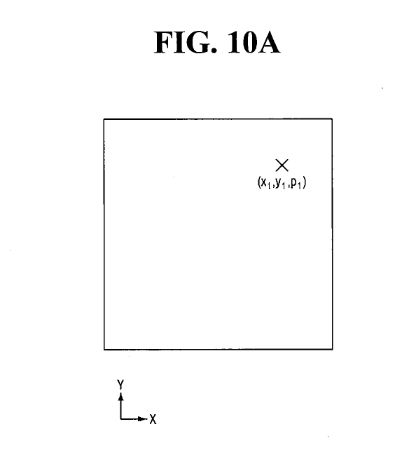

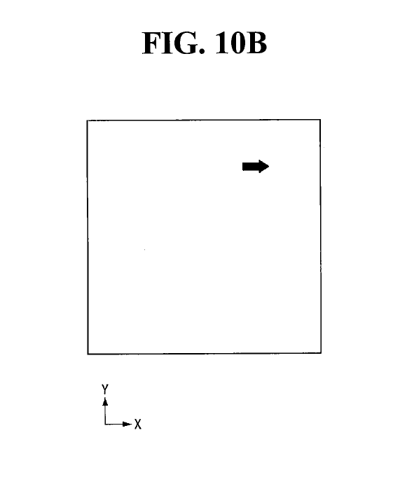

Referring to FIG. 7 again, the correction position of the photomask 102 may be determined when a registration error occurs (S248). Details thereof will be described with reference to FIG. 10A and 10B.

FIGS. 10A and 10B are example views for explaining correction positions of a photomask according to some embodiments.

Referring to FIG. 10A, at least a part of the light absorbing pattern 140 of the photomask 102 may cause a registration error. At this time, in order to correct the registration error, a suitable position to be irradiated by a laser may be determined. Further, the degree of correction at the corresponding position may be determined. The correction position may be a specific coordinate (e.g., x-y coordinate) of the photomask 102. Further, the correction degree may be such a degree that the photomask 102 needs to be corrected. For example, in some embodiments, the correction degree may be a power of a laser. For example, in some embodiments, the correction degree may be laser irradiation time. For example, the coordinates (x1, y1, p1) shown in FIG. 10A may be an x-axis position, a y-axis position, and a laser power p1, respectively. However, the present inventive concept is not limited thereto. For example, the correction degree may include both the laser irradiation time and the laser output power. Those skilled in the art may control various factors to effectively correct registration errors.

Referring to FIG. 10B, at least a part of the light absorbing pattern 140 of the photomask 102 may cause a registration error. At this time, an appropriate correction position and correction degree for correcting registration errors may be determined. The correction position and the correction degree may be indicated by an arrow. For example, the head of the arrow may be a correction position. That is, the head of the arrow may be a position where a laser should be irradiated. For example, the length of the arrow may be correction degree. For example, the length of the arrow may be laser irradiation time. For example, the length of the arrow may be laser output power. However, the present inventive concept is not limited thereto.

FIGS. 10A and 10B are only views for explaining an example method of expressing a correction position and correction degree according to some embodiments. Those skilled in the art will be able to express the correction position and correction degree in various manners.

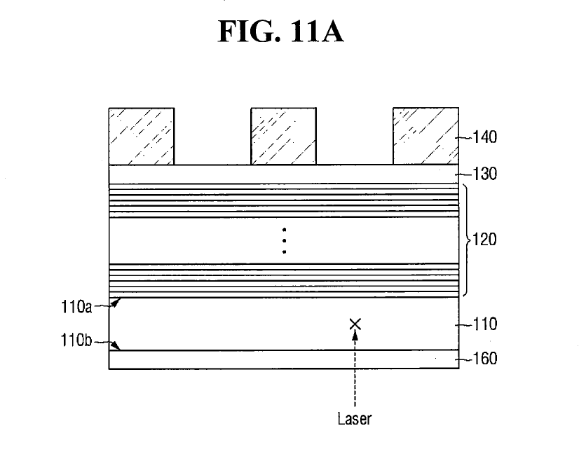

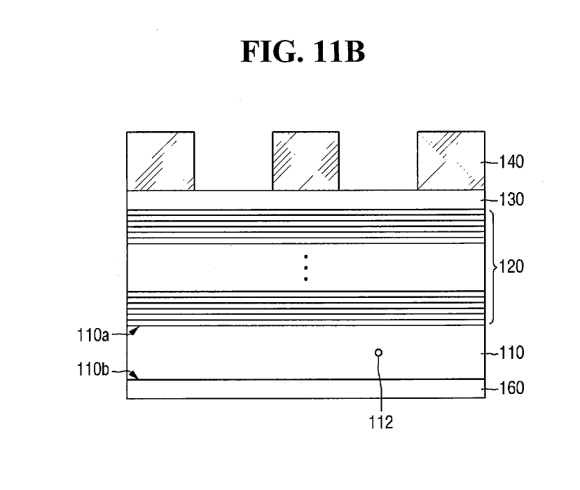

FIGS. 11A and 11B are example views for explaining a process of correcting registration errors according to some embodiments.

Referring to FIGS. 2, 11A, and 11B, correction defects 112 may be formed in the low thermal expansion material substrate 110 by irradiating a laser (S250). More specifically, as shown in FIG. 11A, the photomask 102 may be irradiated with a laser at a determined correction position. That is, on the conductive film 160 of the photomask 102, the laser may be irradiated toward the determined correction position. Further, when the laser is irradiated to the determined correction position, the output power or output time of the laser may be adjusted according to a determined correction degree. At least a part of the irradiated laser may penetrate the conductive layer to be injected into the low thermal expansion material substrate 110. In this case, since the light transmittance of the conductive layer 160 in the visible light range is at least 10%, at least 10% of the irradiated laser may penetrate the conductive layer 160. As shown in FIG. 11B, the laser penetrating the conductive layer 160 and injected into the low thermal expansion material substrate 110 may form one or more correction defects 112 in the low thermal expansion material substrate 110. In some embodiments, the wavelength of the laser used to correct the registration errors may be 532 nm.

The correction defects 112 may form specific structural defects from the inside of the low thermal expansion material substrate 110 to the bottom of the light absorbing pattern 140. The specific structural defects formed may correct the registration errors of the photomask 102. That is, the correction defects 112 may not be naturally formed defects but may be defects formed intentionally to correct the registration errors.

Although it is shown in FIGS. 11A and 11B that a correction defect 112 is included in the low thermal expansion material substrate 110 under an area in which the light absorbing pattern 140 is formed, the present inventive concept is not limited thereto. For example, the correction defect 112 may be formed at a portion where the light absorbing pattern 140 is not formed, that is, at the frame portion of the photomask 100. Those skilled in the art may determine a position at which the correction defect is formed, and may form the correction defect 112 at the corresponding position.

In some embodiments, it has been described that the process of detecting registration errors and correcting them is performed only once, but the present inventive concept is not limited thereto. In some other embodiments, the process of detecting and correcting registration errors may be repeatedly performed a plurality of times. For example, the photomask 102 may be a first corrected photomask in which a first correction defect is formed. Subsequently, an extreme ultraviolet photolithography process using the first corrected photomask may be performed. Thereafter, a registration error may be detected by comparing the newly formed pattern with the originally designed pattern. Thereafter, the newly formed pattern is compared with the initially designed pattern to detect registration errors. Subsequently, the correction position and correction degree for correcting the registration error may be determined. Then, the first corrected photomask may be formed with a second correction defect. These processes may be repeated to form a finally corrected photomask 100.

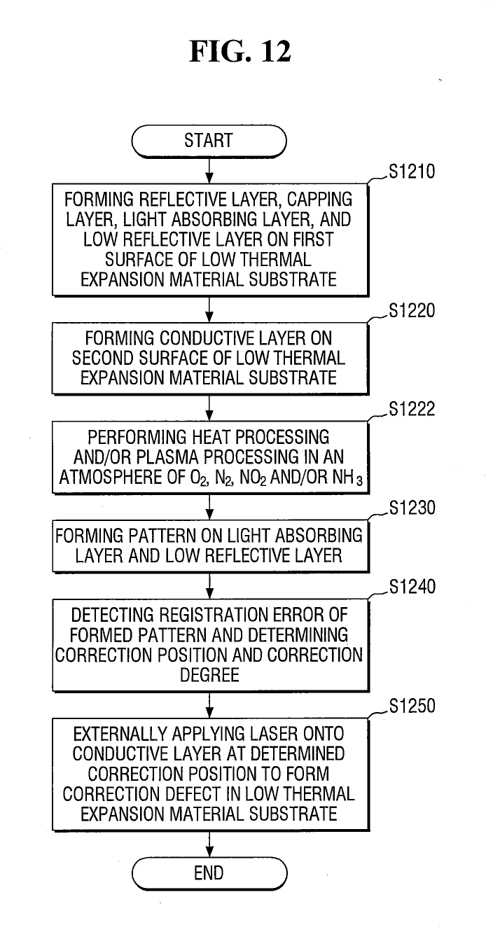

FIG. 12 is an example flowchart for explaining a method of manufacturing a photomask according to some embodiments. For convenience of explanation, duplicate or similar contents will be omitted or briefly described.

A reflective layer 120, a capping layer 130, a light absorbing layer 140a, and a low reflective layer 150 may be sequentially formed on the first surface 110a of a low thermal expansion material substrate 110 (S1210).

A conductive layer 160 may be formed on the second surface 110b of the low thermal expansion material substrate 110 (S1220).

Heat processing and/or plasma processing may be performed on the conductive layer 160 in an atmosphere of oxygen gas (O₂), nitrogen gas (N₂), nitrogen dioxide gas (NO₂), and/or ammonia gas (NH₃) (S1222).

For example, after the conductive layer 160 is formed, heat processing may be performed on the conductive layer 160 in an atmosphere of oxygen gas (O₂), nitrogen gas (N₂), nitrogen dioxide gas (NO₂), and/or ammonia gas (NH₃). The heat processing may be performed, for example, using a hot plate, a furnace, and/or a laser. For example, in the case of using a hot plate, the hot plate may be set to an appropriate temperature in an atmosphere of oxygen gas (O₂), nitrogen gas (N₂), nitrogen dioxide gas (NO₂), and/or ammonia gas (NH₃). The conductive layer 160 may be mounted so as to be in contact with the hot plate thereby conducting heat. Thereby, the heat treatment of the conductive layer 160 may be performed.

The light transmittance of the conductive layer 160 having been performed by heat processing and/or plasma processing in an atmosphere of oxygen gas (O₂), nitrogen gas (N₂), nitrogen dioxide gas (NO₂), and/or ammonia gas (NH₃) may increase in the visible light range. The surface resistance of the conductive layer 160 having been performed by heat processing and/or plasma processing in an atmosphere of oxygen gas (O₂), nitrogen gas (N₂), nitrogen dioxide gas (NO₂), and/or ammonia gas (NH₃) may decrease. The thickness of the conductive layer 160 having been performed by heat processing and/or plasma processing in an atmosphere of oxygen gas (O₂), nitrogen gas (N₂), nitrogen dioxide gas (NO₂), and/or ammonia gas (NH₃) may be greater than that of the conductive layer before the heat processing and/or plasma processing. The mechanical/chemical durability of the conductive layer 160 having been performed by heat processing and/or plasma processing in an atmosphere of oxygen gas (O₂), nitrogen gas (N₂), nitrogen dioxide gas (NO₂), and/or ammonia gas (NH₃) may increase.

A pattern may be formed on the light absorbing layer 140a and the low reflective layer 150 (S1230).

The registration error of the formed pattern may be detected, and the correction position and degree may be determined (S1240).

Correction defects 112 may be formed in the low thermal expansion substrate 110 by irradiating a laser (S1250).

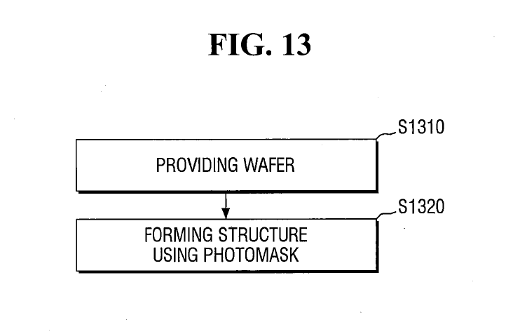

FIG. 13 is an example flowchart for explaining a method of manufacturing a semiconductor device using the photomask according to some embodiments.

A wafer is provided to semiconductor device manufacturing equipment (S1310).

A structure is formed on the wafer using the photomask 100, and a specific process is performed, thereby manufacturing a semiconductor device (S1320).

The photomask 100 in FIG. 13 may be the photomask having been described with reference to FIGS. 1 to 12.

For example, a wafer may be provided to a deposition/thin film process equipment. The provided wafer may be subjected to a deposition/thin film process. Further, a photoresist may be applied on the wafer. The applied photoresist may be patterned through extreme ultraviolet photolithography using the photomask 100. An etching process may be performed using the photoresist pattern obtained by pattering the photoresist. Further, after the structure is formed, the structure may be subjected to a packaging process. Through the above processes, a semiconductor device may be manufactured.

Although the example embodiments of the present inventive concept have been disclosed for illustrative purposes, those skilled in the art will appreciate that various modifications, additions and substitutions are possible, without departing from the scope and spirit of the inventive concept as disclosed in the accompanying claims.

What is claimed is:

1. A photomask, comprising:
a low thermal expansion material (LTEM) substrate comprising a first surface opposing a second surface of the LTEM substrate;
a reflective layer on the first surface of the low thermal expansion material substrate, the reflective layer comprising first material layers and second material layers which are stacked alternately;
a light absorbing pattern on the reflective layer; and
a conductive layer on the second surface of the low thermal expansion material substrate,
wherein the low thermal expansion material substrate comprises a correction defect intentionally formed in the LTEM substrate to correct the light absorbing pattern, and
wherein the conductive layer comprises one of ruthenium oxide (RuO₂), iridium oxide (IrO₂), and/or a combination thereof.

2. The photomask of claim 1,
wherein the conductive layer has a transmittance of at least 10% in a visible light range and a surface resistance of less than or equal to 200 ohm/sq.

3. The photomask of claim 1,
wherein the conductive layer comprises a ruthenium oxide layer.

4. The photomask of claim 3,
wherein the conductive layer has a thickness of 30 nm to 128 nm.

5. The photomask of claim 3,
wherein the conductive layer has a transmittance of 20% to 55% in a visible light range.

6. The photomask of claim 3,
wherein the conductive layer has a surface resistance of 25 ohm/sq to 100 ohm/sq.

7. The photomask of claim 1,
wherein the first material layers of the reflective layer comprise silicon (Si), and/or the second material layers of the reflective layer comprise molybdenum (Mo).

8. The photomask of claim 1, further comprising:
a capping layer between the reflective layer and the light absorbing pattern.

9. The photomask of claim 8,
wherein the capping layer comprises one of ruthenium (Ru) or a ruthenium alloy.

10. A method of manufacturing a photomask, comprising:
forming a reflective layer on a first surface of a low thermal expansion material (LTEM) substrate, the reflective layer comprising first material layers and second material layers which are stacked alternately;
forming a light absorbing layer on the reflective layer; and
forming a conductive layer on a second surface of the low thermal expansion material substrate,
wherein the second surface of the LTEM substrate opposes the first surface of the LTEM substrate, and
wherein the conductive layer is formed from one of ruthenium oxide (RuO₂), iridium oxide (IrO₂), and/or a combination thereof.

11. The method of claim 10,
wherein the conductive layer has a transmittance of at least 10% in a visible light range and a surface resistance of less than or equal to 200 ohm/sq.

12. The method of claim 10,
wherein the first material layers of the reflective layer comprise silicon (Si), and/or the second material layers of the reflective layer comprise molybdenum (Mo), and
wherein the first material layers and the second material layers are formed by sputtering.

13. The method of claim 10, wherein, the forming the conductive layer on the second surface of the low thermal expansion material substrate comprises:
forming the conductive layer through reactive sputtering by forming an atmosphere of argon (Ar) and oxygen (O₂); and
selecting at least one of ruthenium (Ru) and/or iridium (Ir) as a target.

14. The method of claim 10, further comprising:
performing heat processing and/or plasma processing of the conductive layer in an atmosphere of at least one of oxygen (O₂), nitrogen (N₂), nitrogen dioxide (NO₂), and/or ammonia (NH₃), after forming the conductive layer on the second surface of the low thermal expansion material substrate.

15. The method of claim 14,
wherein the heat processing is performed using at least one of a hot plate, a furnace, and/or a laser.

16. The method of claim 10, further comprising:
forming a correction defect in the low thermal expansion material substrate based on irradiating the conductive layer,
wherein the correction defect corrects the light absorbing layer based on laser irradiation time and laser output power of a laser used for the irradiating the conductive layer.

17. The method of claim 10, further comprising:
forming a capping layer between the reflective layer and the light absorbing layer.

18. The method of claim 10, further comprising:
forming a low reflective layer on the reflective layer.

19. A method of manufacturing a photomask, comprising:
providing a mask structure comprising one or more of a conductive layer, a low thermal expansion material (LTEM) substrate, a reflective layer, and a light absorbing layer, which are sequentially stacked, the conductive layer being formed from one of ruthenium oxide (RuO₂), iridium oxide (IrO₂), and/or a combination thereof;
patterning the light absorbing layer to form a light absorbing pattern; and
forming a correction defect correcting the light absorbing pattern in the low thermal expansion material substrate.

20. The method of claim 19, wherein the forming the correction defect correcting the light absorbing pattern in the low thermal expansion material substrate comprises:
detecting a registration error of the light absorbing pattern;
determining a correction position of the correction defect in accordance with the detected registration error; and
irradiating the conductive layer at the correction position by a layer that is external to the mask structure,
wherein at least a portion of irradiated light that irradiates the conductive layer forms the correction defect in the low thermal expansion material substrate by transmitting the irradiated light towards the conductive layer.
